(19) United States
(12) Patent Application Publication
(10) Pub. No.: US 2016/0111317 A1
(43) Pub. Date: Apr. 21, 2016

(54) SEMICONDUCTOR MANUFACTURING APPARATUS

(71) Applicant: KABUSHIKI KAISHA TOSHIBA, Tokyo (JP)

(72) Inventors: Shinya FUKAYAMA, Aichi (JP); Yukifumi OYAMA, Mie (JP); Satoshi TSUKIYAMA, Kanagawa (JP); Masatoshi FUKUDA, Mie (JP)

(21) Appl. No.: 14/980,317

(22) Filed: Dec. 28, 2015

Related U.S. Application Data
(62) Division of application No. 14/188,517, filed on Feb. 24, 2014.

(30) Foreign Application Priority Data
Sep. 9, 2013 (JP) 2013-186100

(51) Int. Cl. H01L 21/683; H01L 21/677; H01L 25/00; H01L 23/00

(52) U.S. Cl. CPC H01L 21/6838; H01L 24/81; H01L 24/75; H01L 21/677; H01L 25/50; H01L 2224/7565; H01L 2224/81191

(57) ABSTRACT

A semiconductor manufacturing apparatus includes: a collet which sucks a semiconductor chip having a main surface on which a bump is formed, and an actuator which transfers the sucked semiconductor chip onto a mounting substrate or another semiconductor chip by driving the collet. A recessed portion for avoiding a contact between the collet and the bump is formed on a suction surface of the collet which sucks the semiconductor chip.

### CROSS-REFERENCE TO RELATED APPLICATION

This application is a division of U.S. patent application Ser. No. 14/188,517, filed on Feb. 24, 2014, which is based upon and claims the benefit of priority from Japanese Patent Application No. 2013-186100, filed on Sep. 9, 2013, the entire contents of both applications being incorporated herein by reference.

### FIELD

Embodiments described herein relate to a semiconductor manufacturing apparatus for manufacturing a semiconductor device.

### BACKGROUND

A known semiconductor device includes a plurality of laminated (stacked) semiconductor chips (hereinafter, referred to as “chips”) in a sealed package, and the miniaturization and the reduction of thickness of such semiconductor package has been progressing. In many cases, the respective laminated chips are electrically connected with each other by bonding wires. To miniaturize and reduce the thickness of a semiconductor package, there has been developed a semiconductor device where respective laminated chips are connected with each other using penetrating vias.

To connect the respective chips using penetrating vias, it is necessary to provide bumps on both main surfaces (front surface and back surface) of the chip. However, when the bumps are provided on both main surfaces of the chip, the bumps interfere with a suction surface of a transfer device (pickup machine). Accordingly, a bending stress is generated in the chip during the transfer operation. Further, the bumps of different chips are connected with each other by applying a load to the chips at the time of laminating the chips (e.g. pressure bonding). In such a case, the load is concentrated on the bumps. As a result, the chip can be damaged, thus lowering the reliability of the connection of the chip as well as connections between the chips.

### DESCRIPTION OF THE DRAWINGS

FIG. 1A and FIG. 1B are side views of a semiconductor manufacturing apparatus according to an embodiment.

FIG. 2A and FIG. 2B are views of a collet used in the semiconductor manufacturing apparatus according to the embodiment includes.

FIG. 3 is a cross-sectional view showing a state where a chip is sucked to the collet according to the embodiment.

FIG. 4 is a cross-sectional view showing a state where a chip is sucked to a collet according to a comparison example.

FIG. 5 is a plan view of a semiconductor chip.

FIG. 6 is a graph showing an amount of deformation of the chip when the chip is sucked to the collet according to the embodiment.

FIG. 7 is a graph showing an amount of deformation of the chip when the chip is sucked to the collet according to the comparison example.

### DETAILED DESCRIPTION

According to an embodiment, there is provided a semiconductor manufacturing apparatus which can minimize the generation of a bending stress in a semiconductor chip.

In general, according to one embodiment, a semiconductor manufacturing apparatus includes: a collet which holds a semiconductor chip having a main surface on which a bump is formed by suction; and an actuator which places the semiconductor chip being held on a mounting substrate or on another semiconductor chip by manipulating the collet. A recessed portion for avoiding contact between the collet and the bump is formed on a suction surface of the collet which sucks the semiconductor chip.

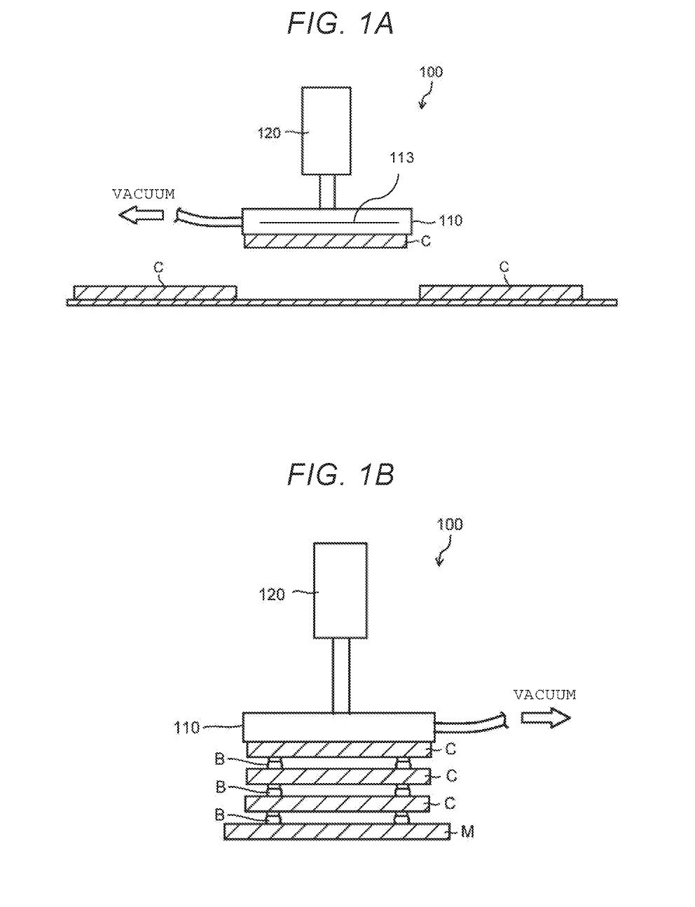

Hereinafter, one embodiment of a method of manufacturing a semiconductor device and a semiconductor manufacturing apparatus is explained in conjunction with FIG. 1 to FIG. 3 and FIG. 5 to FIG. 6. In the respective embodiments, substantially the same constituent parts are given the same symbols, and the repeated explanation of these parts is omitted for brevity. However, the semiconductor manufacturing apparatus is schematically shown in the drawings and hence, the relationship between thicknesses and planar sizes, ratio between thicknesses of respective layers, scale, and the like, differ from those of a semiconductor manufacturing apparatus which is actually manufactured. Terms which indicate directions such as “up” and “down” in the explanation made hereinafter indicate the relative directions and may not indicate the directions according to gravitational force.

### EMBODIMENT

FIGS. 1A and 1B are side views of a semiconductor manufacturing apparatus 100 according to an embodiment. The semiconductor manufacturing apparatus 100 is a flip chip bonder where a semiconductor chip (hereinafter, referred to as “chip”) is connected to a mounting substrate or another chip by flip chip connection.

The semiconductor manufacturing apparatus 100 includes at least: a collet 110 which can hold a chip C by vacuum; and an actuator 120 which places the chip C held by the collet 110 by vacuum on a mounting substrate M or another chip C by moving the collet 110 to position the chip C for placement on an underlying element, and removing the vacuum suction to release the chip C from the collet 110. The semiconductor manufacturing apparatus 100 picks up the chip C by vacuum suction (see FIG. 1A), and the picked-up chip C is moved to and mounted on the mounting substrate M or another chip C (see FIG. 1B).

Bumps B for connection are mounted on both main surfaces (front surface and back surface) of the chip C. The bumps B mounted on both main surfaces are electrically connected with each other through penetrating vias not shown in the drawing. In this embodiment, by connecting the bumps B mounted on both main surfaces with each other, the chips C are laminated on each other and are electrically connected with each other. As shown in FIG. 1B, with respect to the laminated chips C, it is possible to omit the bumps B on an upper surface side of the uppermost chip C assuming a backside of the uppermost chip C includes bumps B.

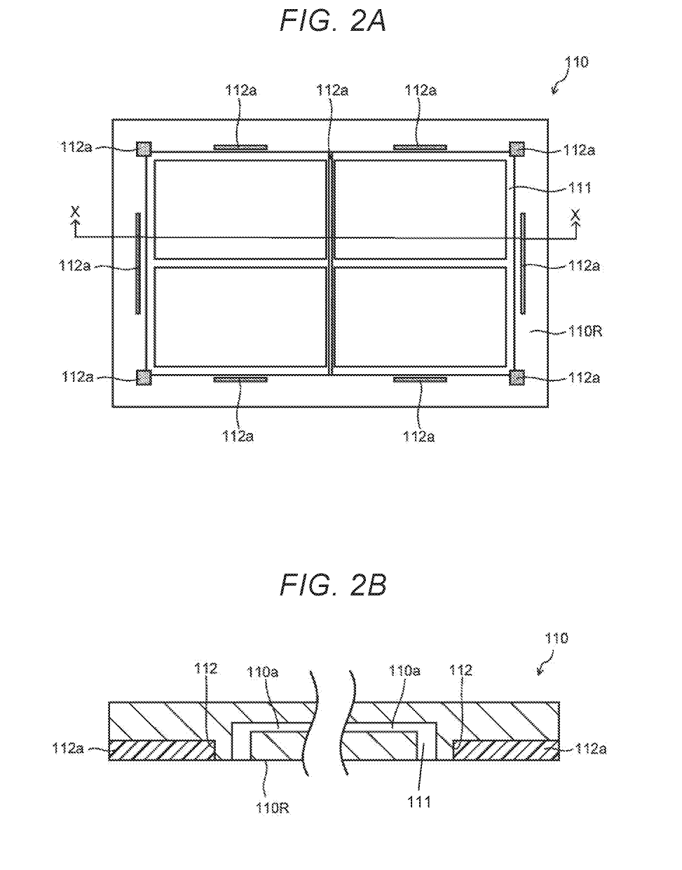

FIG. 2A and FIG. 2B are views of the collet 110. FIG. 2A is a plan view (back surface view) of the collet 110, and FIG. 2B is a cross-sectional view of the collet 110 taken along a line X-X in FIG. 2A. As shown in FIG. 2A, a back surface 110R of the collet 110 has a rectangular shape as viewed in the plan view in conformity with a shape of the chip C. The back surface 110R of the collet 110 forms a suction surface for sucking up and holding the chip C, and a groove 111, for providing the vacuum top suck and hold the chip C, is formed on the back surface 110R.

As shown in FIG. 2B, channels 110a which are in fluid communication with the groove 111 formed on the back surface 110R are formed in the inside of the collet 110. The channels 110a are connected to a vacuum pump not shown in the drawing. By sucking air in the channels 110a by vacuum, the chip C may be sucked by vacuum to the back surface 110R of the collet 110 and held there.

Further, recessed portions 112 are formed on the back surface 110R of the collet 110 for avoiding the contact between the collet 110 and the bumps B of the chip C (shown in FIG. 1B). Although the recessed portions 112 are formed on peripheral portions and a center portion of the back surface 110R in FIG. 2A, positions where the recessed portions 112 are formed may be arbitrarily determined, and are suitably changed according to positions of the bumps B mounted on the chip C.

Elastic materials 112a are provided in the recessed portions 112. By mounting an elastic material 112a in a recessed portion 112, it is possible to minimize pressure on the bumps B and therefore suppress the generation of a bending stress in the chip C when the chip is held by the collet 110. As such, a sufficient pressure can be applied to chip C to transfer the chip C efficiently while minimizing a bending moment in the chip C. As a material for forming the elastic material 112a, a material which exhibits high thermal conductivity and high heat resistance property such as rubber made of silicone, fluororesin, ethylene vinyl acetate or a foam material made of these materials to enhance transmission of heat to the chip C from a heater 113 (FIG. 1A). Further, a front surface of the elastic material 112a and the back surface 110R comprise a substantially flat surface (the outer surface of the elastic material 112a and the back surface 110R are substantially coplanar).

A thickness T of the elastic material 112a (or the depth of the recessed portions 112) may be set to about 10 μm, or more to about 50 μm, or less. When the thickness T of the elastic material 112a is excessively large, heat is not transmitted to the chip C efficiently. On the other hand, when the thickness T of the elastic material 112a is excessively small, it is difficult to suppress generation of a bending stress in the chip C. In the case where a pressure can be sufficiently applied to the chip C to facilitate transfer without bending the chip C excessively even when elastic materials 112a is not provided, elastic materials 112a within the recessed portions 112 are not always necessary.

A heater 113 (shown in FIG. 1A) which is made of a nichrome wire, ceramic, or the like, is embedded in the collet 110. By supplying electricity to the heater, the collet 110 is heated to about 100 degrees Celsius (° C.) to 300° C. In mounting the chip C on the mounting substrate M or another chip C, the chip C is heated by the above-mentioned heater 113 in a state where a pressure in the downward direction is applied to the chip C. A solder is melted by such heating so that the bumps B on the chip C are connected to the mounting substrate M or another chip C.

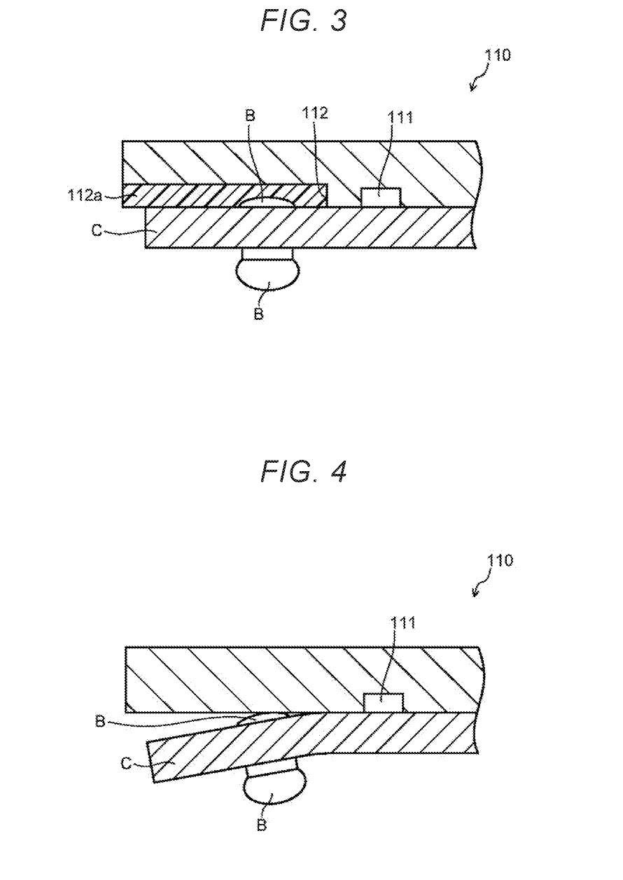

FIG. 3 is a cross-sectional view showing a state where a chip C is held by the collet 110 by vacuum suction. FIG. 4 is a cross-sectional view showing a state where a chip C is held by a collet 110A by vacuum suction according to a comparison example. In FIG. 3, the recessed portion 112 is formed on the back surface 110R of the collet 110 for avoiding contact between rigid surfaces of the collet 110 and the bump B of the chip C. Due to the recessed portion 112, rigid surfaces of the collet 110 and the bump B are not brought into direct contact with each other. Further, with the provision of the elastic material 112a, stress generated by the pushing of the collet against the bump B is absorbed and attenuated. Accordingly, the generation of a bending moment in the chip C can be suppressed.

On the other hand, in FIG. 4, a recessed portion 112 for avoiding the contact between a collet 110 and a bump B of a chip C is not formed on a back surface 110R of the collet 110. Accordingly, the collet 110 and the bump B are brought into direct contact with each other so that a bending stress is generated in the chip C.

As has been explained heretofore, the semiconductor manufacturing apparatus 100 includes: the collet 110 which holds, by vacuum, a chip C having main surfaces on which the bumps B are formed; and the actuator 120 which places the chip C held by vacuum on the mounting substrate M or another chip C by manipulating the collet 110 to the desired position on the underlying member. The recessed portions 112 which avoid a contact between the collet 110 and the bumps B are formed on the back surface 110R of the collet 110 which constitutes a suction surface for sucking the chip C. Due to such constitution, the generation of a bending stress in the chip C may be suppressed.

Elastic materials 112a are provided in the recessed portions 112. Due to such constitution, when the chip C is connected by flip chip connection, a sufficient pressure can be applied to the chip C by the collet 110 without bending the chip C. Since the chip C is not bent, the bumps B may be sufficiently connected during manufacture of the semiconductor device. Accordingly, the reliability of the bump connection of the semiconductor device is enhanced.

When the thickness T of the elastic material 112a is set to 10 μm or greater, it is possible to suppress generation of a bending stress in the chip C. When the thickness T of the elastic material 112a is set to 50 μm or less, it is also possible to transfer heat to the chip C for solder connecting the bumps of adjacent chips C. Accordingly, the reliability of the connection of the chip C is further enhanced.

### Example

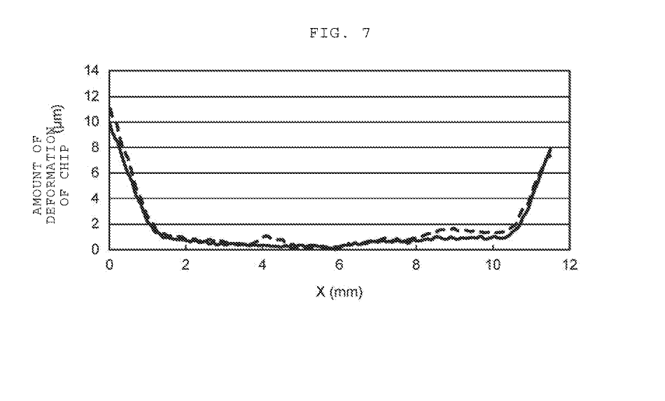

Next, an example is explained in conjunction with FIG. 6 and compared to a comparative example in FIG. 7. In this example, an amount of deformation of a chip when the chip is sucked is measured with respect to the collet (example) as in FIG. 2, where the recessed portions are formed on the back surface of the collet for avoiding the contact between the collet surface and a bump. In the comparative example, a collet is used where recessed portions are not formed for avoiding the contact between the collet and bumps (comparison example). Elastic materials are not filled in the recessed portions of the collet according to the comparative example.

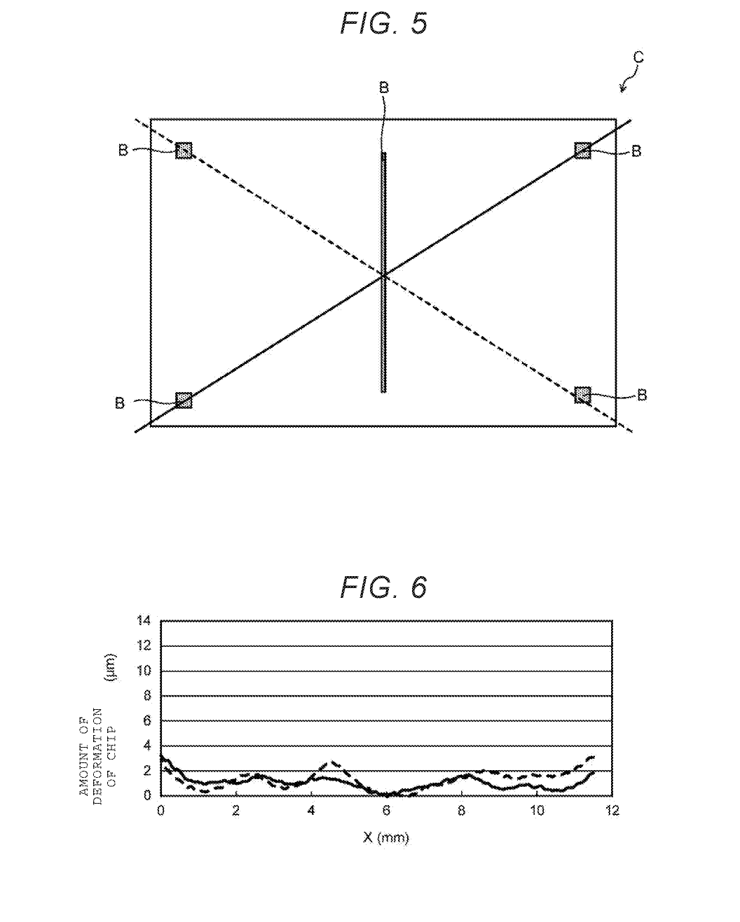

FIG. 5 is a plan view of a chip. In FIG. 5, the amount of deformation of a chip is measured as indicated by a solid diagonal line and a dashed diagonal line. In this example, an amount of deformation of the chip is measured along the diagonal lines of the chip as shown in FIG. 5.

FIG. 6 is a graph showing an amount of deformation of a chip when the chip is sucked by the collet (having recessed portions, such as in FIG. 2) of the example. An amount of deformation of the chip along the solid diagonal line in FIG. 5 is indicated by a solid line in FIG. 6. An amount of deformation of the chip along the dashed diagonal line in FIG. 5 is indicated by a dashed line in FIG. 6. As shown in FIG. 6, in the collet of the example, the bumps formed on the chip are not brought into contact with the collet due to the recessed portions. Accordingly, an amount of deformation of the chip is suppressed to about 3 μm even in a region where the bumps are present (0 to 2 μm and 10 to 12 μm).

FIG. 7 is a graph showing an amount of deformation of a chip when the chip is sucked by the collet (not having recessed portions) of the comparison example. An amount of deformation of the chip along the solid diagonal line in FIG. 5 is indicated by a solid line in FIG. 7. An amount of deformation of a chip along the dashed diagonal line in FIG. 5 is indicated by a dashed line in FIG. 7. As shown in FIG. 7, in the collet of the comparison example, there are no recessed portions and hence, bumps formed on the chip are brought into contact with the collet so that a bending stress is generated in the chip. Accordingly, an amount of deformation of the chip is sharply increased in regions where the bumps are present (0 to 2 μm and 10 to 12 μm).

As described above, according to this example, it is found that, by forming the recessed portions for avoiding contact between the collet and the bumps on the suction surface (back surface) of the collet for sucking a chip, it is possible to efficiently suppress the generation of a bending stress in the chip.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing method comprising:
positioning a collet including a suction surface having a recessed portion such that a position of the recessed portion corresponds to a position of a bump on a semiconductor chip, the suction surface configured to hold the semiconductor chip having a main surface on which the bump has been formed, the main surface of the semiconductor chip to be held by vacuum suction to the suction surface; and
transferring the semiconductor chip onto a mounting substrate or another semiconductor chip by manipulation of the collet, wherein
an elastic material having a thickness of about 10 μm to about 50 μm is disposed on the recessed portion.

2. The semiconductor manufacturing method according to claim 1, wherein
the recessed portion is positioned interior of an edge of the suction surface.

3. The semiconductor manufacturing method according to claim 2, wherein
the collet comprises a plurality of recessed portions formed in the suction surface of the collet.

4. The semiconductor manufacturing method according to claim 3, wherein
the suction surface of the collet is rectangular in plan view, and the plurality of recessed portions are provided at corners of the suction surface and correspond to the location of bumps on the semiconductor chip.

5. The semiconductor manufacturing method according to claim 4, wherein
the plurality of recessed portions are provided along sides of the suction surface.

6. The semiconductor manufacturing method according to claim 1, wherein
the collet comprises a plurality of recessed portions formed in the suction surface of the collet.

7. The semiconductor manufacturing method according to claim 6, wherein
the suction surface of the collet is rectangular in plan view, and the plurality of recessed portions are provided at corners of the suction surface.

8. The semiconductor manufacturing method according to claim 7, wherein
the plurality of recessed portions are provided along sides of the suction surface.

9. A semiconductor manufacturing method, comprising:
transferring a semiconductor chip using a collet having a suction surface that holds a main surface of the semiconductor chip on which a plurality of bumps are formed, the suction surface having a plurality of recessed portions formed therein at positions corresponding to each of the bumps; wherein
an actuator positions the collet such that the plurality of recessed portions and the plurality of bumps are at corresponding positions before transferring the semiconductor chip onto a mounting substrate or another semiconductor chip by moving of the collet, and
the plurality of recessed portions are sized to avoid a contact between the collet and the plurality of bumps on the semiconductor chip.

10. The semiconductor manufacturing method according to claim 9, wherein
an elastic material is provided in each of the plurality of recessed portions.

11. The semiconductor manufacturing method according to claim 10, wherein
the suction surface of the collet is rectangular in plan view, and the plurality of recessed portions are provided at corners of the suction surface.

12. The semiconductor manufacturing method according to claim 11, wherein
the plurality of recessed portions are provided along sides of the suction surface.

13. The semiconductor manufacturing method according to claim 10, wherein
a thickness of the elastic material is about 10 μm to about 50 μm.

14. The semiconductor manufacturing method according to claim 9, wherein
the suction surface of the collet is rectangular in plan view, and the plurality of recessed portions are provided at corners of the suction surface.

15. The semiconductor manufacturing method according to claim 14, wherein
an elastic material is provided in each of the plurality of recessed portions.

16. The semiconductor manufacturing method according to claim 15, wherein
a thickness of the elastic material is about 10 μm to about 50 μm.

17. The semiconductor manufacturing method according to claim 14, wherein
the collet includes a heater.

18. The semiconductor manufacturing method according to claim 17, wherein
an elastic material is provided in each of the plurality of recessed portions.

19. The semiconductor manufacturing method according to claim 18, wherein
a thickness of the elastic material is about 10 μm to about 50 μm.

20. A semiconductor manufacturing method comprising:
transferring a semiconductor chip using a collet configured to hold the semiconductor chip on a main surface thereof and on which a plurality of bumps are formed, the collet having a suction surface configured to hold the main surface of the semiconductor chip by suction, the suction surface having a plurality of recessed portions formed therein at positions that correspond to positions of the plurality of bumps; and
positioning the collet using an actuator configured to position the collet such that the plurality of recessed portions and the plurality of bumps are at corresponding positions before transferring and transfers the semiconductor chip onto a mounting substrate or another semiconductor chip by movement of the collet, wherein
the plurality of recessed portions formed on the suction surface of the collet are sized to avoid a contact between the collet and the plurality of bumps on the semiconductor chip, and
an elastic material having a thickness of about 10 μm to about 50 μm is disposed in each of the plurality of recessed portions.
